(19) United States
(12) Patent Application Publication
(10) Pub. No.: US 2023/0411492 A1
(43) Pub. Date: Dec. 21, 2023

(54) STRUCTURE AND FORMATION METHOD OF SEMICONDUCTOR DEVICE WITH GATE STACK

(71) Applicant: Taiwan Semiconductor Manufacturing Company, Ltd., Hsinchu (TW)

(72) Inventors: Chun-Yi CHANG, Hsinchu City (TW); Wen-Li CHIU, Kaohsiung City (TW); Hsin-Che CHIANG, Taipei City (TW); Chun-Sheng LIANG, Puyan Township (TW)

(73) Assignee: Taiwan Semiconductor Manufacturing Company, Ltd., Hsinchu (TW)

(21) Appl. No.: 17/841,314

(22) Filed: Jun. 15, 2022

(51) Int. Cl. H01L 29/66; H01L 29/06; H01L 29/417; H01L 29/423; H01L 29/786; H01L 29/775; H01L 21/02; H01L 21/3115

(52) U.S. Cl. CPC H01L 29/66545; H01L 29/0673; H01L 29/41733; H01L 29/42392; H01L 29/78696; H01L 29/775; H01L 21/02603; H01L 21/31155; H01L 29/66742; H01L 29/66439

(57) ABSTRACT

A semiconductor device structure and a formation method are provided. The method includes forming a dummy gate stack over a substrate and forming a dielectric layer laterally surrounding the dummy gate stack. The method also includes introducing dopants into an upper portion of the dielectric layer and removing the dummy gate stack to form a trench surrounded by the dielectric layer. The method further includes forming a metal gate stack in the trench.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2D are cross-sectional views of various stages of a process for forming a portion of a semiconductor device structure, in accordance with some embodiments.

FIGS. 3A-3Q are cross-sectional views of various stages of a process for forming a portion of a semiconductor device structure, in accordance with some embodiments.

FIG. 4 is a cross-sectional view of an intermediate stage of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins and/or gate all around (GAA) transistor structures (which include channel layers suspended over a substrate, where the channel layers are fabricated from semiconductor layers stacks (i.e., fins)). The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

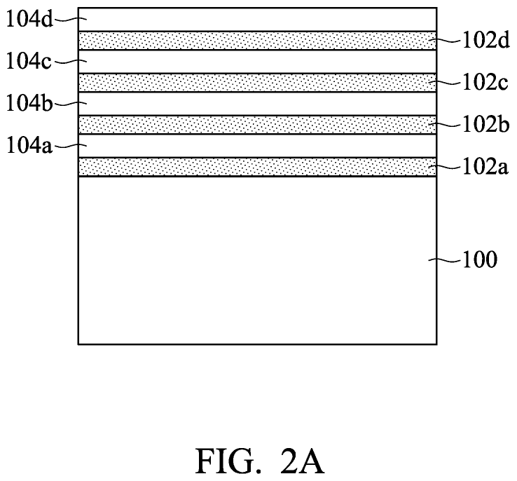

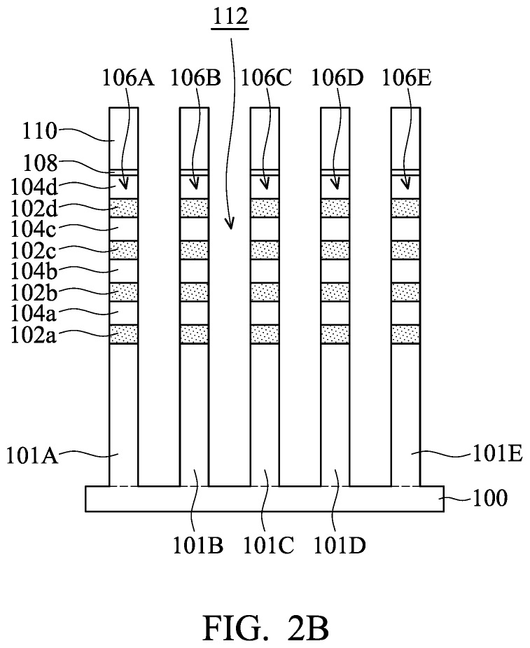

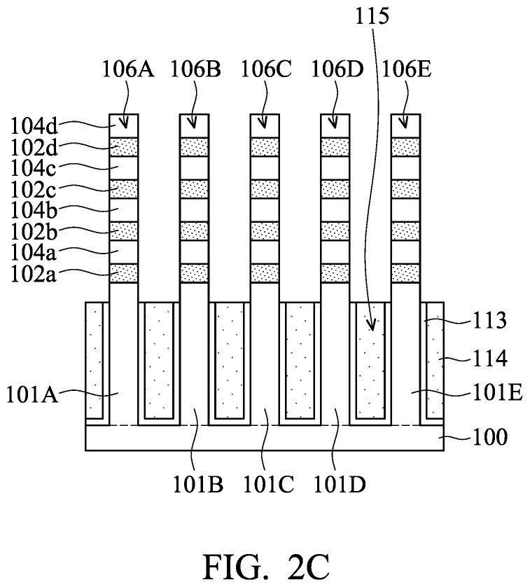

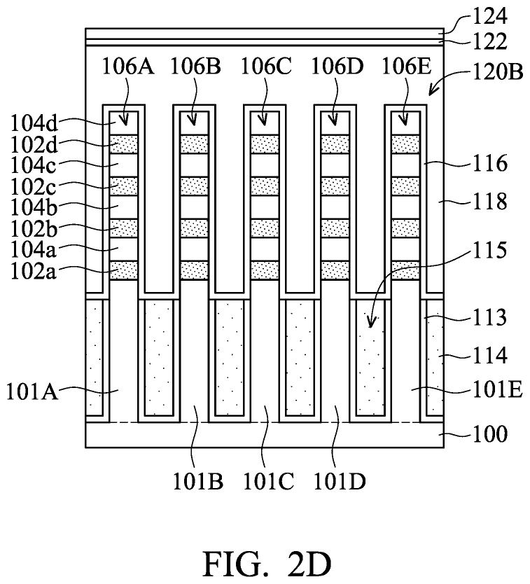

FIGS. 2A-2D are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, 102c, and 102d. The semiconductor stack also includes multiple semiconductor layers 104a, 104b, 104c, and 104d. In some embodiments, the semiconductor layers 102a-102d and the semiconductor layers 104a-104d are laid out alternately, as shown in FIG. 2A. The semiconductor layers 102a-102d and the semiconductor layers 104a-104d have an alternating configuration, as shown in FIG. 2A.

In some embodiments, the semiconductor layers 102a-102d function as sacrificial layers that will be removed in a subsequent process to release the semiconductor layers 104a-104d. The semiconductor layers 104a-104d that are released may function as channel structures of one or more transistors.

In some embodiments, the semiconductor layers 104a-104d that will be used to form channel structures are made of a material that is different than that of the semiconductor layers 102a-102d. In some embodiments, the semiconductor layers 104a-104d are made of or include silicon, germanium, other suitable materials, or a combination thereof. In some embodiments, the semiconductor layers 102a-102d are made of or include silicon germanium. In some other embodiments, the semiconductor layers 104a-104d are made of silicon germanium, and the semiconductor layers 102a-102d are made of silicon germanium with different atomic concentration of germanium than that of the semiconductor layers 104a-104d. As a result, different etching selectivity and/or different oxidation rates during subsequent processing may be achieved between the semiconductor layers 102a-102d and the semiconductor layers 104a-104d.

The present disclosure contemplates that the semiconductor layers 102a-102d and the semiconductor layers 104a-104d include any combination of semiconductor materials that can provide desired etching selectivity, desired oxidation rate differences, and/or desired performance characteristics (e.g., materials that maximize current flow).

In some embodiments, the semiconductor layers 102a-102d and 104a-104d are formed using multiple epitaxial growth operations. Each of the semiconductor layers 102a-102d and 104a-104d may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the semiconductor layers 102a-102d and 104a-104d are grown in-situ in the same process chamber. In some embodiments, the growth of the semiconductor layers 102a-102d and 104a-104d are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer 108 and a second mask layer 110. The first mask layer 108 and the second mask layer 110 may be made of different materials. One or more photolithography processes and one or more etching processes are used to pattern the semiconductor stack into multiple fin structures 106A, 106B, 106C, 106D, and 106E. The fin structures 106A-106E may be patterned by any suitable method. For example, the fin structures 106A-106E may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple trenches 112, as shown in FIG. 2B. Each of the fin structures may include portions of the semiconductor layers 102a-102d and 104a-104d and multiple semiconductor fins 101A, 101B, 101C, 101D, and 101E, as shown in FIG. 2B. The semiconductor substrate 100 may also be partially removed during the etching process that forms the fin structures 106A-106E. Protruding portions of the semiconductor substrate 100 that remain form the semiconductor fins 101A-101E.

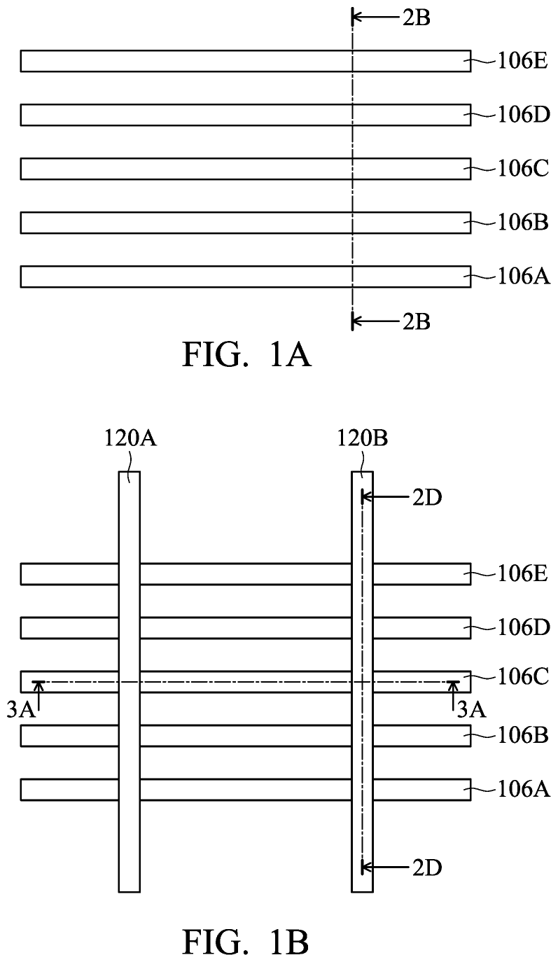

FIGS. 1A-1B are top views of various stages of a process for forming a portion of a semiconductor device structure, in accordance with some embodiments. As shown in FIG. 1A, multiple fin structures 106A-106E are formed, in accordance with some embodiments. In some embodiments, the fin structures 106A-106E are oriented lengthwise. In some embodiments, the extending directions of the fin structures 106A-106E are substantially parallel to each other, as shown in FIG. 1A. In some embodiments, FIG. 2B is a cross-sectional view of the structure taken along the line 2B-2B in FIG. 1A.

Afterwards, as shown in FIG. 2C, an isolation structure 115 is formed to surround lower portions of the fin structures 106A-106E, in accordance with some embodiments. In some embodiments, the isolation structure 115 includes dielectric fillings 114 and a liner layer 113 that is adjacent to the semiconductor fins 101A-101E.

In some embodiments, one or more dielectric layers are deposited over the fin structures 106A-106E and the semiconductor substrate 100. The dielectric layers for forming the dielectric fillings 114 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof.

The liner layer 113 may be made of or include silicon nitride, silicon oxynitride, silicon carbide, silicon oxycarbide, one or more other suitable materials, or a combination thereof. The dielectric layers and the liner layer 113 may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner layer 113. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner layer 113. As a result, the remaining portion of the dielectric layers forms the dielectric fillings 114 of the isolation structure 115. Upper portions of the fin structures 106A-106E protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level, as shown in FIG. 2C. In some embodiments, the topmost surface of the isolation structure 115 is below the bottommost surface of the semiconductor layer 102a that functions as a sacrificial layer.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 115.

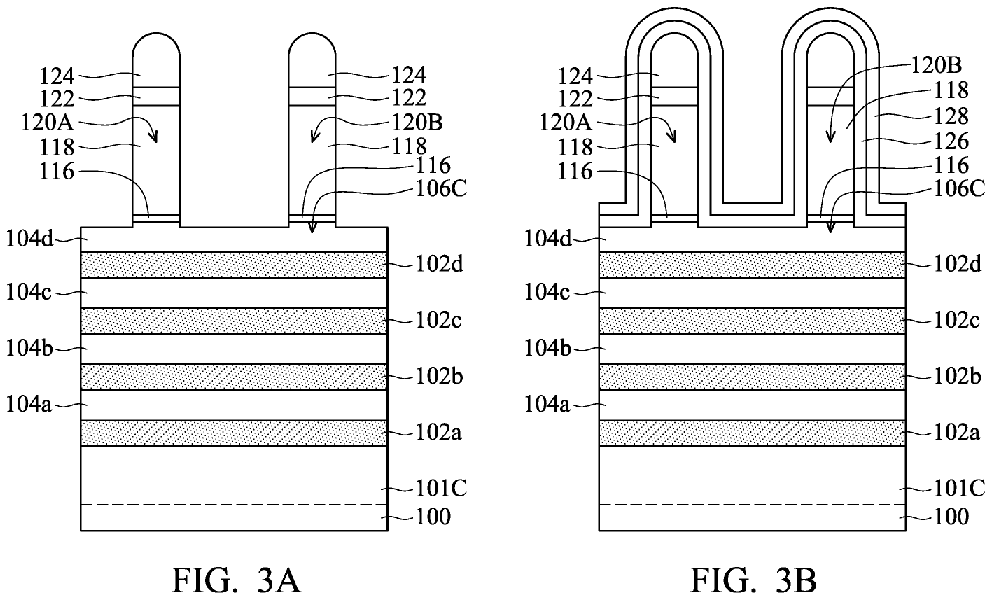

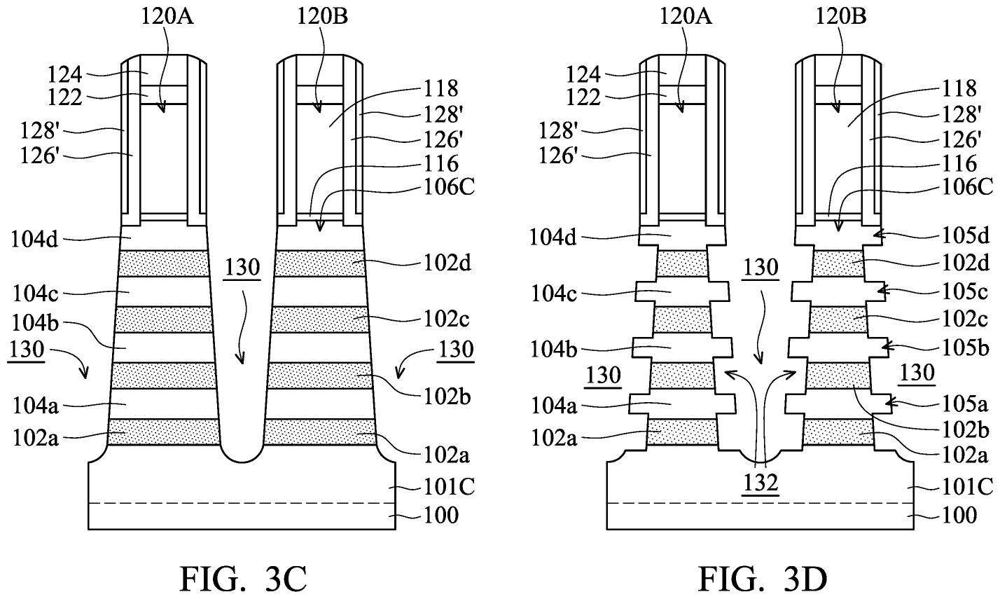

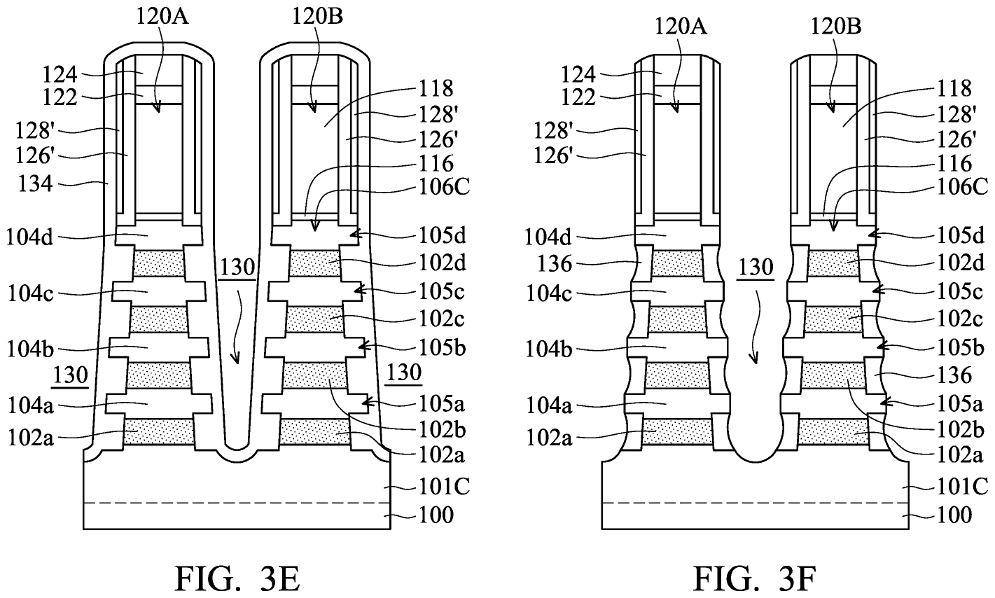

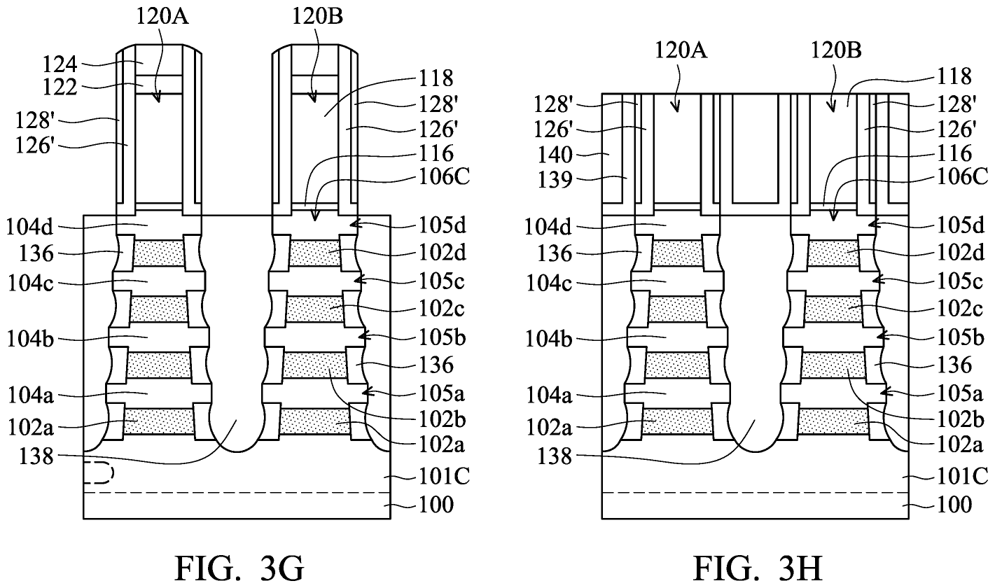

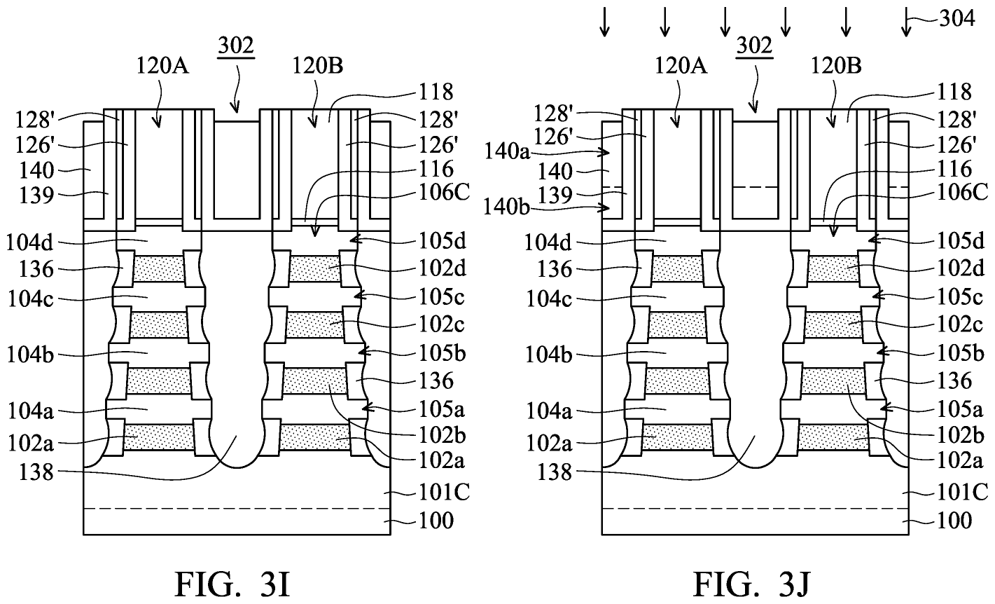

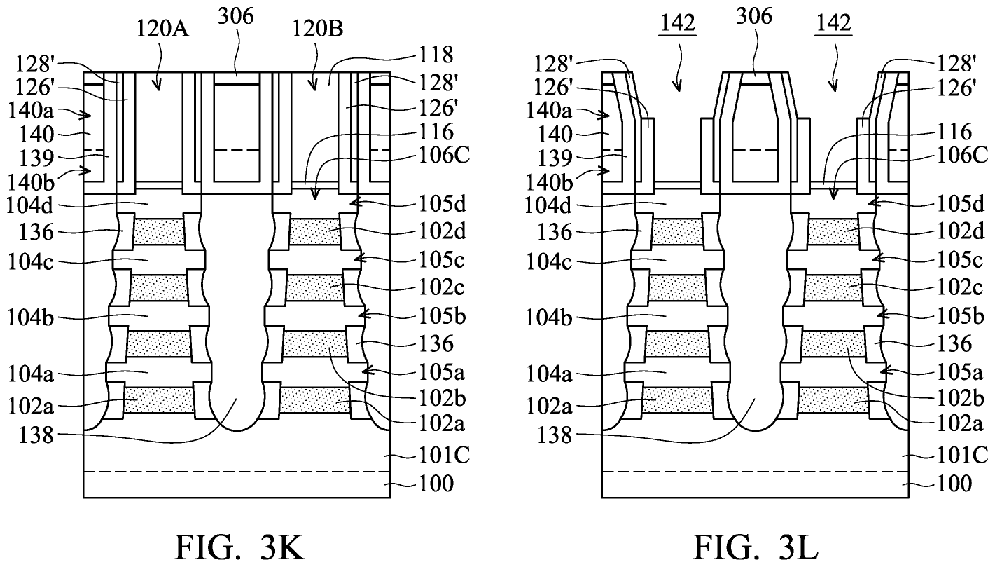

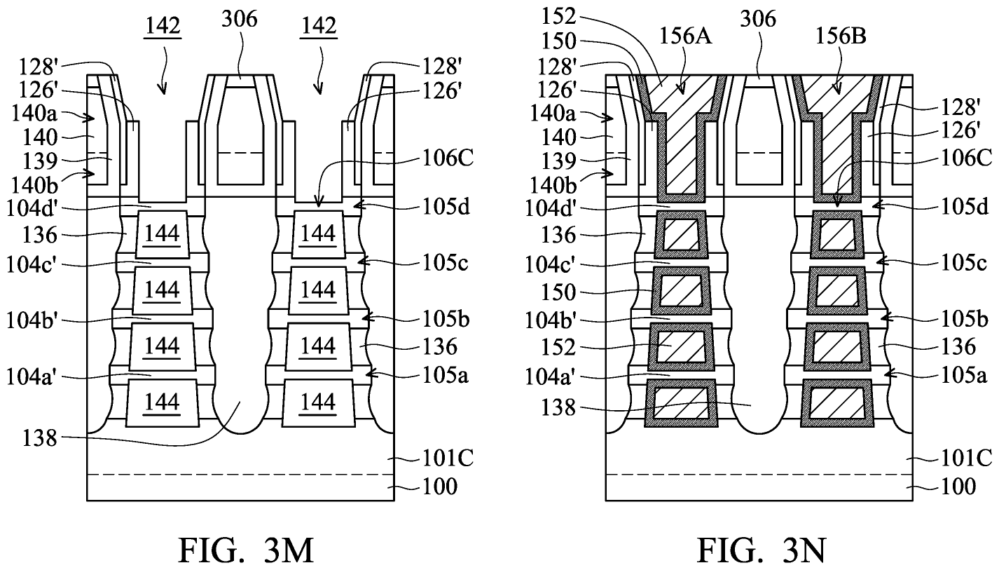

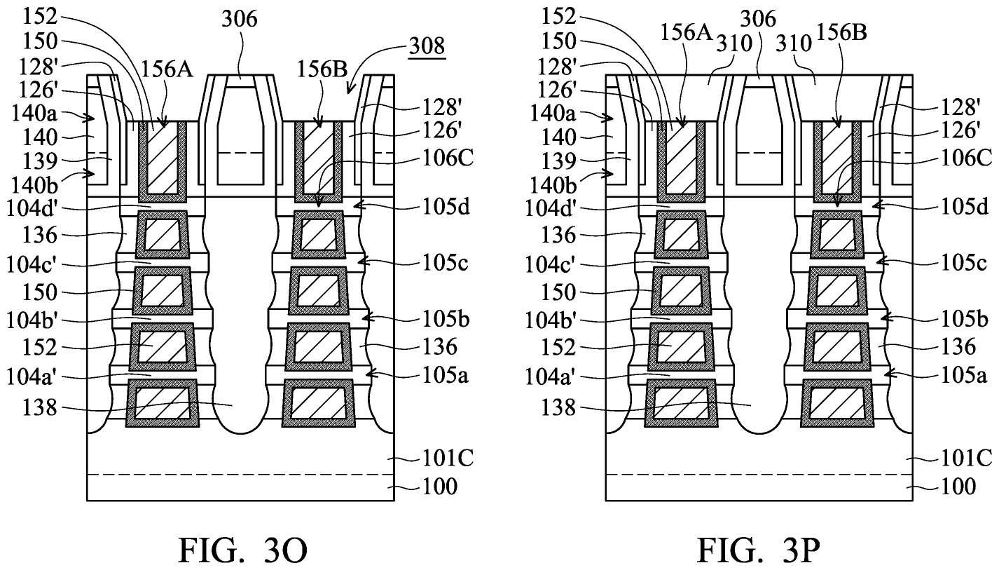

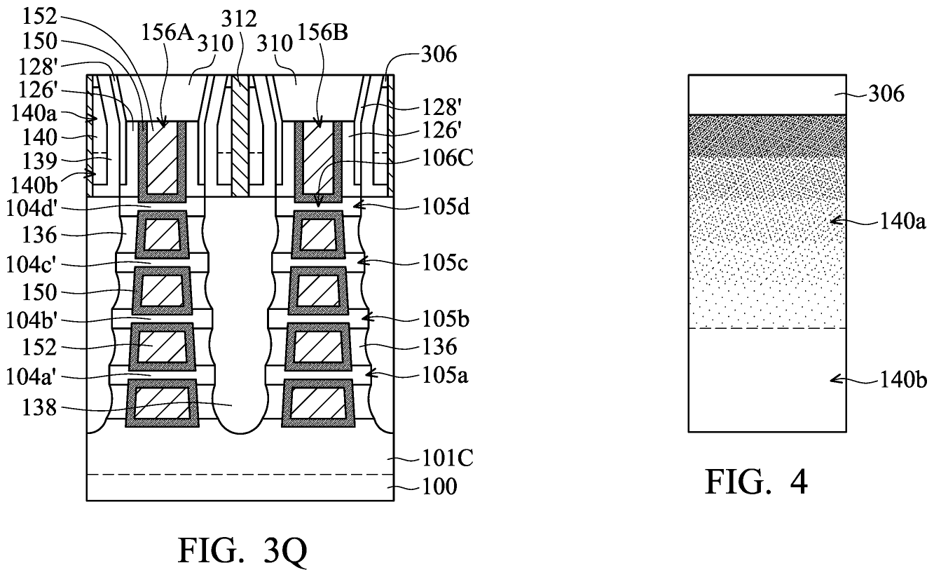

Afterwards, dummy gate stacks 120A and 120B are formed to extend across the fin structures 106A-106E, as shown in FIG. 1B in accordance with some embodiments. In some embodiments, FIG. 2D is a cross-sectional view of the structure taken along the line 2D-2D in FIG. 1B. FIGS. 3A-3Q are cross-sectional views of various stages of a process for forming a portion of a semiconductor device structure, in accordance with some embodiments. In some embodiments, FIG. 3A is a cross-sectional view of the structure taken along the lines 3A-3A in FIG. 1B.

As shown in FIGS. 1B, 2D, and 3A, the dummy gate stacks 120A and 120B are formed to partially cover and to extend across the fin structures 106A-106E, in accordance with some embodiments. In some embodiments, the dummy gate stacks 120A and 120B wraps around the fin structures 106A-106E. As shown in FIG. 2D, the dummy gate stack 120B extends across and is wrapped around the fin structures 106A-106E. As shown in FIG. 1B, other portions of the fin structures 106A-106E are exposed without being covered by the dummy gate stacks 120A and 120B.

As shown in FIGS. 2D and 3A, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A-106E. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements including mask layers 122 and 124 are used to assist in the patterning process for forming the dummy gate stacks 120A and 120B. With the hard mask elements as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIG. 3B, spacer layers 126 and 128 are then deposited over the dummy gate stacks 120A and 120B and the fin structure 106C, in accordance with some embodiments. The spacer layers 126 and 128 extend along the tops and sidewalls of the dummy gate stacks 120A and 120B, as shown in FIG. 3B.

In some embodiments, the spacer layers 126 and 128 are made of different materials. The spacer layer 126 may be made of a dielectric material that has a low dielectric constant. The spacer layer 126 may be made of or include silicon carbide, silicon oxycarbide, carbon-containing silicon oxynitride, silicon oxide, one or more other suitable materials, or a combination thereof. In some embodiments, the spacer layer 126 is a single layer. In some other embodiments, the spacer layer 126 includes multiple sub-layers. Some of the sub-layers may be made of different materials. Some of the sub-layers may be made of similar materials with different compositions. For example, one of the sub-layers may have a greater atomic concentration of carbon than other sub-layers.

The spacer layer 128 may be made of a dielectric material that can provide more protection to the gate stacks during subsequent processes. The spacer layer 128 may have a greater dielectric constant than that of the spacer layer 126. The spacer layer 128 may be made of silicon nitride, silicon oxynitride, carbon-containing silicon nitride, carbon-containing silicon oxynitride, one or more other suitable materials, or a combination thereof. The spacer layers 126 and 128 may be sequentially deposited using a CVD process, an ALD process, a physical vapor deposition (PVD) process, one or more other applicable processes, or a combination thereof.

However, embodiments of the disclosure are not limited thereto. Many variations and/or modifications can be made to embodiments of the disclosure. In some other embodiments, the spacer layers 126 and 128 are made of the same material.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form spacer elements 126′ and 128′, respectively. The spacer elements 126′ and 128′ extend along the sidewalls of the dummy gate stacks 120A and 120B, as shown in FIG. 3C.

Afterwards, the fin structures including the fin structure 106C are partially removed, in accordance with some embodiments. As a result, the recesses 130 are formed, as shown in FIG. 3C. The recesses 130 may be used to contain epitaxial structures (such as source/drain structures) that will be formed later. One or more etching processes may be used to form the recesses 130. In some embodiments, a dry etching process is used to form the recesses 130. Alternatively, a wet etching process may be used to form the recesses 130. In some embodiments, the recesses 130 penetrate into the fin structure 106C. In some embodiments, the recesses 130 further extend into the semiconductor fin 101C, as shown in FIG. 3C. In some embodiments, the spacer elements 126′ and 128′ and the recesses 130 are formed simultaneously using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104d) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104d) is substantially as wide as a lower semiconductor layer (such as the semiconductor layer 104b).

Afterwards, as shown in FIG. 3D, the semiconductor layers 102a-102d are laterally etched, in accordance with some embodiments. As a result, edges of the semiconductor layers 102a-102d retreat from edges of the semiconductor layers 104a-104d. As shown in FIG. 3D, recesses 132 are formed due to the lateral etching of the semiconductor layers 102a-102d. The recesses 132 may be used to contain inner spacers that will be formed later. The semiconductor layers 102a-102d may be laterally etched using a wet etching process, a dry etching process, or a combination thereof. In some other embodiments, the semiconductor layers 102a-102d are partially oxidized before being laterally etched.

During the lateral etching of the semiconductor layers 102a-102d, the semiconductor layers 104a-104d may also be slightly etched. As a result, edge portions of the semiconductor layers 104a-104d are partially etched and thus shrink to become edge elements 105a-105d, as shown in FIG. 3D. As shown in FIG. 3D, each of the edge elements 105a-105d of the semiconductor layers 104a-104d is thinner than the corresponding inner portion of the semiconductor layers 104a-104d.

As shown in FIG. 3E, an insulating layer 134 is deposited over the structure shown in FIG. 3D, in accordance with some embodiments. The insulating layer 134 covers the dummy gate stacks 120A and 120B and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, one or more other suitable materials, or a combination thereof. In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, one or more other applicable processes, or a combination thereof.

As shown in FIG. 3F, an etching process is used to partially remove the insulating layer 134, in accordance with some embodiments. The portions of the insulating layer 134 outside of the recesses 132 may be removed. The remaining portions of the insulating layer 134 form inner spacers 136, as shown in FIG. 3F. The etching process may include a dry etching process, a wet etching process, or a combination thereof.

The inner spacers 136 cover the edges of the semiconductor layers 102a-102d. The inner spacers 136 may be used to prevent subsequently formed epitaxial structures (that function as, for example, source/drain structures) from being damaged during a subsequent process for removing the sacrificial layers 102a-102d. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101C originally covered by the insulating layer 134 are exposed by the recesses 130, as shown in FIG. 3F. The edges of the semiconductor layers 104a-104d are also exposed by the recesses 130, as shown in FIG. 3F.

As shown in FIG. 3G, epitaxial structures 138 are formed in the recesses 130, in accordance with some embodiments. In some other embodiments, the epitaxial structures 138 overfill the recesses 130 to ensure full contact between the epitaxial structures 138 and the semiconductor layers 104d. In some embodiments, the top surfaces of the epitaxial structures 138 are higher than the top surface of the dummy gate dielectric layer 116. In some other embodiments, the epitaxial structures 138 partially fill the recesses 130.

In some embodiments, the epitaxial structures 138 connect to the semiconductor layers 104a-104d. Portions of the semiconductor layers 104a-104d that will be function as channel structures are sandwiched between two respective epitaxial structures 138, as shown in FIG. 3G. In some embodiments, the epitaxial structures 138 are designed to function as source/drain structures of p-channel field-effect transistors (PFET). The epitaxial structures 138 may include epitaxially grown silicon germanium (SiGe), epitaxially grown silicon, or another suitable epitaxially grown semiconductor material. In some other embodiments, the epitaxial structures 138 are designed to function as source/drain structures of n-channel field-effect transistors (NFET). The epitaxial structures 138 may include epitaxially grown silicon or another suitable epitaxially grown semiconductor material. The source/drain structure(s) may refer to a source structure or a drain structure, individually or collectively dependent upon the context.

In some embodiments, the epitaxial structures 138 are designed to function as source/drain structures of n-channel field-effect transistors (NFET). In these cases, the epitaxial structure 138 is n-type doped. In some embodiments, the epitaxial structures 138 is doped with one or more suitable n-type dopants. For example, the epitaxial structures 138 is a Si source/drain feature that is doped with phosphor (P), antimony (Sb), arsenic (As), or another suitable dopant.

Embodiments of the disclosure are not limited thereto. Many variations and/or modifications can be made to embodiments of the disclosure. In some other embodiments, the epitaxial structures 138 are designed to function as source/drain structures of p-channel field-effect transistors (PFET). In these cases, the epitaxial structure 138 is p-type doped. In some embodiments, the epitaxial structures 138 is doped with one or more suitable p-type dopants. For example, the epitaxial structures 138 is a SiGe source/drain feature or a Si source/drain feature that is doped with boron (B), gallium (Ga), indium (In), or another suitable dopant.

In some embodiments, the epitaxial structures 138 are formed using multiple epitaxial growth operations. In some embodiments, these epitaxial growth operations are performed in-situ in the same process chamber. In some embodiments, the vacuum of the process chamber is not broken before the formation of the epitaxial structures 138 is accomplished. The reaction gases may be varied in the reaction chamber during the epitaxial growth operations.

These epitaxial growth operations may be achieved using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof. In some embodiments, the formation of the epitaxial structures 138 involves one or more etching processes that are used to fine-tune the shapes of the epitaxial structures 138.

In some embodiments, the epitaxial structures 138 are doped in-situ during their epitaxial growth. The initial reaction gas mixture for forming the epitaxial structures 138 contains respective dopants. In some embodiments, the epitaxial structures 138 are further exposed to one or more annealing processes to activate the dopants. For example, a rapid thermal annealing process is used.

Afterwards, as shown in FIG. 3H, a contact etch stop layer 139 and a dielectric layer 140 are formed to cover the epitaxial structures 138 and to surround the dummy gate stacks 120A and 120B, in accordance with some embodiments. The contact etch stop layer 139 may be made of or include silicon nitride, silicon oxynitride, silicon carbide, aluminum oxide, one or more other suitable materials, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof.

In some embodiments, an etch stop material layer and a dielectric material layer are sequentially deposited. The etch stop material layer may be deposited using a CVD process, an ALD process, a PVD process, one or more other applicable processes, or a combination thereof. The dielectric material layer may be deposited using an FCVD process, a CVD process, an ALD process, one or more other applicable processes, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3H. The planarization process may include a CMP process, a grinding process, an etching process, a dry polishing process, one or more other applicable processes, or a combination thereof. In some embodiments, the mask layers 122 and 124 are removed during the planarization process. In some embodiments, after the planarization process, the top surfaces of the contact etch stop layer 139, the dielectric layer 140, and the dummy gate electrodes 118 are substantially level.

As shown in FIG. 3I, the dielectric layer 140 is etched back to be lower than the tops of the contact etch stop layer 139 and the dummy gate electrodes 118, in accordance with some embodiments. As a result, recesses 302 are formed over the remaining portions of the dielectric layer 140. The recesses 302 may be used to contain protective caps that will be formed later.

As shown in FIG. 3J, before the formation of the protective caps, dopants are introduced into the dielectric layer 140, in accordance with some embodiments. An introduction process 304 may be used to introduce dopants into the dielectric layer 140. The implanted dopants may include nitrogen (N), argon (Ar), germanium (Ge), one or more other suitable elements, or a combination thereof. The implanted dopants may function as strain tuning elements that tune and/or change the strain of the dielectric layer 140. For example, portions of the dielectric layer 140 may be turned to have compressive strain.

The introduction process 304 may include an implantation process such as an ion implantation process. The implantation energy may be within a range from about 1 keV to about 7 keV. The implantation angle may be within a range from about 1 degree to about 70 degrees. In some embodiments, the implantation angle is varied during the introduction process 304. The implantation dose may be within a range from about 10¹⁵ cm⁻² to about 10¹⁶ cm⁻².

In some embodiments, the implanted dopants disperse in an upper portion 140a of the dielectric layer 140, as shown in FIG. 3I. In some embodiments, the implanted dopants do not reach a lower portion 140b of the dielectric layer 140. In some embodiments, the lower portion 140b of the dielectric layer 140 is substantially free of implanted dopants.

Afterwards, the dielectric layer 140 is thermally annealed using one or more thermal processes, in accordance with some embodiments. The thermal process may be used to repair defects resulting from the introduction process 304. The dielectric layer 140 may be annealed using a micro-second annealing (uSSA) process, rapid thermal annealing (RTA), laser spike annealing (LSA), one or more other applicable processes, or a combination thereof. The annealing temperature may be within a range from about 800 degrees C. to about 1200 degrees C. In some embodiments, a micro-second annealing (uSSA) process is used to thermally anneal the dielectric layer 140 and the implanted dopants for a very short time period, so as to prevent from negatively affecting the quality and reliability of the epitaxial structures 138.

As shown in FIG. 3K, protective caps 306 are formed in the recesses 302, in accordance with some embodiments. The protective caps 306 may be used to protect the dielectric layer 140 thereunder during subsequent processes. The protective caps 306 may be made of or include silicon nitride, silicon oxynitride, silicon carbide, carbon-containing silicon nitride, carbon-containing silicon oxynitride, aluminum oxide, one or more other suitable materials, or a combination thereof.

In some embodiments, a protective material layer is deposited to overfill the recesses 302. The protective material layer may be deposited using an ALD process, a CVD process, one or more other applicable processes, or a combination thereof. Afterwards, a planarization process is used to remove the portions of the protective material layer outside of the recesses 302. As a result, the remaining portions of the protective material layer form the protective caps 306. In some embodiments, the top surfaces of the contact etch stop layer 139, the protective caps 306, and the dummy gate electrodes 118 are substantially level.

Many variations and/or modifications can be made to embodiments of the disclosure. In some other embodiments, the recesses 302 and the protective caps 306 are not formed.

FIG. 4 is a cross-sectional view of an intermediate stage of a process for forming a portion of a semiconductor device structure, in accordance with some embodiments. In some embodiments, FIG. 4 is an enlarged cross-sectional view showing a portion of the structure shown in FIG. 3K.

As shown in FIG. 4, the dotted points are used to represent the implanted dopants. In some embodiments, the atomic concentration of implanted dopants of the upper portion 140a of the dielectric layer 140 gradually decreases from the top of the dielectric layer 140 towards the lower portion 140b of the dielectric layer 140b.

Afterwards, as shown in FIG. 3L, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116. In some embodiments, the upper portion of each of the trenches 142 is wider than the lower portion of each of the trenches 142, as shown in FIG. 3L. In some embodiments, the spacer elements 126′ are partially removed during the one or more etching processes for forming the trenches 142, as shown in FIG. 3L.

As mentioned above, the implanted dopants may function as strain tuning elements that tune and/or change the strain of the dielectric layer 140. For example, portions of the dielectric layer 140 may be turned to have compressive strain. Therefore, after the removal of the dummy gate electrodes 118, the compressive strain may cause the upper portions of the trenches 142 expand to be wider than the lower portions of the trenches 142. Due to the implanted dopants, the trenches 142 may have profiles that facilitate the following formation of metal gate stacks.

As shown in FIG. 3M, the dummy gate dielectric layer 116 and the semiconductor layers 102a-102d (that function as sacrificial layers) are removed, in accordance with some embodiments. In some embodiments, one or more etching processes are used to remove the dummy gate dielectric layer 116 and the semiconductor layers 102a-102d. As a result, recesses 144 are formed, as shown in FIG. 3M.

Due to high etching selectivity, the semiconductor layers 104a-104d are slightly (or substantially not) etched. The remaining portions of the semiconductor layers 104a-104d form multiple semiconductor nanostructures 104a′-104d′. The semiconductor nanostructures 104a′-104d′ are constructed by or made up of the remaining portions of the semiconductor layers 104a-104d. The semiconductor nanostructures 104a′-104d′ may function as channel structures of transistors.

In some embodiments, the etchant used for removing the semiconductor layers 102a-102d also slightly removes the semiconductor layers 104a-104d that form the semiconductor nanostructures 104a′-104d′. As a result, the obtained semiconductor nanostructures 104a′-104d′ become thinner after the removal of the semiconductor layers 102a-102d. In some embodiments, each of the semiconductor nanostructures 104a′-104d′ is thinner than the edge portions 105a-105d since the edge portions 105a-105d are surrounded by other elements and thus are prevented from being reached and etched by the etchant.

After the removal of the semiconductor layers 102a-102d (that function as sacrificial layers), the recesses 144 are formed. The recesses 144 connect to the trench 142 and surround each of the semiconductor nanostructures 104a′-104d′. As shown in FIG. 3M, even if the recesses 144 between the semiconductor nanostructures 104a′-104d′ are formed, the semiconductor nanostructures 104a′-104d′ remain held by the epitaxial structures 138. Therefore, after the removal of the semiconductor layers 102a-102d (that function as sacrificial layers), the released semiconductor nanostructures 104a′-104d′ are prevented from falling.

During the removal of the semiconductor layers 102a-102d (that function as sacrificial layers), the inner spacers 136 protect the epitaxial structures 138 from being etched or damaged. The quality and reliability of the semiconductor device structure are improved.

As shown in FIG. 3N, metal gate stacks 156A and 156B are formed to fill the trenches 142, in accordance with some embodiments. The metal gate stacks 156A and 156B further extend into the recesses 144 to wrap around each of the semiconductor nanostructures 104a′-104d′. In some embodiments, the tops of the metal gate stacks 156A and 156B are wider than the tops of the dummy gate stacks 120A and 120B.

As mentioned above, due to the implanted dopants, the trenches 142 may have profiles that facilitate the formation of metal gate stacks 156A and 156B. In some embodiments, the upper portions of the metal gate stacks 156A and 156B are wider than the lower portions of the metal gate stacks 156A and 156B. In some embodiments, there is no void formed in the metal gate stacks 156A and 156B. In some other embodiments, the void formed in the metal gate stacks 156A and 156B are very small.

Each of the metal gate stacks 156A and 156B includes multiple metal gate stack layers. Each of the metal gate stacks 156A and 156B may include a gate dielectric layer 150 and a metal gate electrode 152. The metal gate electrode 152 may include a work function layer. The metal gate electrode 152 may further include a conductive filling. In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104d′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, one or more other applicable processes, or a combination thereof.

In some embodiments, before the formation of the gate dielectric layer 150, interfacial layers are formed on the surfaces of the semiconductor nanostructures 104a′-104d′. The interfacial layers are very thin and are made of silicon oxide or germanium oxide, for example. In some embodiments, the interfacial layers are formed by applying an oxidizing agent on the surfaces of the semiconductor nanostructures 104a′-104d′. For example, a hydrogen peroxide-containing liquid may be provided or applied on the surfaces of the semiconductor nanostructures 104a′-104d′ so as to form the interfacial layers. In some embodiments, the introduction process 304 and the following thermal annealing process significantly reduce hydroxyl group bonding in the dielectric layer 140. There is thus less oxygen diffusing to the positions where the interfacial layers grow. The performance and reliability of the semiconductor device structure may be improved.

The work function layer of the metal gate electrode 152 may be used to provide the desired work function for transistors to enhance device performance including improved threshold voltage. In some embodiments, the work function layer is used for forming a PMOS device. The work function layer is a p-type work function layer. The p-type work function layer is capable of providing a work function value suitable for the device, which may be equal to or greater than about 4.8 eV.

The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof.

In some embodiments, the work function layer is used for forming an NMOS device. The work function layer is an n-type work function layer. The n-type work function layer is capable of providing a work function value suitable for the device, which may be equal to or less than about 4.5 eV.

The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function is an aluminum-containing layer. The aluminum-containing layer may be made of or include TiAlC, TiAlO, TiAlN, one or more other suitable materials, or a combination thereof.

The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer may be fine-tuned to adjust the work function level.

The work function layer may be deposited over the gate dielectric layer 150 using an ALD process, a CVD process, a PVD process, an electroplating process, an electroless plating process, one or more other applicable processes, or a combination thereof. In some embodiments, the formation of the work function layer involves one or more patterning processes. As a result, the n-type work function layer and the n-type work function layer are selectively formed over respective regions.

In some embodiments, a barrier layer is formed before the work function layer to interface the gate dielectric layer 150 with the subsequently formed work function layer. The barrier layer may also be used to prevent diffusion between the gate dielectric layer 150 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the conductive fillings of the metal gate electrodes 152 are made of or include a metal material. The metal material may include tungsten, aluminum, copper, cobalt, one or more other suitable materials, or a combination thereof. A conductive layer used for forming the conductive filling may be deposited over the work function layer using a CVD process, an ALD process, a PVD process, an electroplating process, an electroless plating process, a spin coating process, one or more other applicable processes, or a combination thereof.

In some embodiments, a blocking layer is formed over the work function layer before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

Afterwards, a planarization process is performed to remove the portions of the metal gate stack layers outside of the trenches 142, in accordance with some embodiments. As a result, the remaining portions of the metal gate stack layers form the metal gate stacks 156A and 156B, as shown in FIG. 3N.

In some embodiments, the conductive filling does not extend into the recesses 144 since the recesses 144 are small and have been filled with other elements such as the gate dielectric layer 150 and the work function layer. However, embodiments of the disclosure are not limited thereto. In some other embodiments, a portion of the conductive filling extends into the recesses 144, especially for the lower recesses 144 that may have larger space.

In some other cases, if no dopant is introduced into the dielectric layer 140, the upper portions of the trenches 142 may be narrower due to the tensile strain of the dielectric layer 140. The profile may result in poor gap filling of the multiple metal gate stack layers, which may lead to the formation of voids in the metal gate stack. The performance and reliability of the semiconductor device structure may thus be negatively affected.

Afterwards, as shown in FIG. 3O, the upper portions of the metal gate stacks 156A and 156B are removed, in accordance with some embodiments. As a result, recesses 308 are formed. In some embodiments, an etching back process is used to recess the metal gate stacks 156A and 156B. As mentioned above, due to the implanted dopants, the trenches 142 may have profiles that facilitate the formation of the metal gate stacks 156A and 156B. There is no void or only small void formed in the metal gate stacks 156A and 156B. The metal punch risk during the etching back process of the metal gate stacks 156A and 156B is significantly reduced. The performance and reliability of the semiconductor device structure are greatly improved.

As shown in FIG. 3P, protective structures 310 are formed over the metal gate stacks 156A and 156B to fill the recesses 308, in accordance with some embodiments. In some embodiments, the tops of the protective structures 310 are closer to the top of the dielectric layer 140 than the metal gate stacks 156A and 156B, as shown in FIG. 3P.

The protective structures 310 may be made of or include silicon nitride, silicon oxynitride, silicon carbide, silicon carbon nitride, oxide, another similar material, another suitable material, or a combination thereof. In some embodiments, a protective material layer is deposited to overfill the recesses 308. The protective material layer may be deposited using an ALD process, a CVD process, an FCVD process, one or more other applicable processes, or a combination thereof.

Afterwards, the portions of the protective material layer outside of the recesses 308 are removed. As a result, the remaining portion of the protective material layer in the recesses 308 form the protective structures 310, as shown in FIG. 3P. In some embodiments, a planarization process is used to partially remove the protective material layer. In some embodiments, the planarization process includes a CMP process, a grinding process, an etching process, one or more other applicable processes, or a combination thereof.

Afterwards, as shown in FIG. 3Q, conductive contacts 312 are formed over the epitaxial structures 138, in accordance with some embodiments. The conductive contacts 312 are used to provide electrical connection to the epitaxial structures 138. The conductive contacts 312 may be made of or include cobalt, tungsten, ruthenium, one or more other suitable materials, or a combination thereof. Metal-semiconductor compound elements may be formed between the conductive contacts 312 and the epitaxial structures 138. The metal-semiconductor compound elements may be made of or include titanium silicide, nickel silicide, cobalt silicide, titanium silicon germanium, one or more other suitable materials, or a combination thereof. The formation of the metal-semiconductor compound elements and the conductive contacts 312 may involve one or more patterning processes, one or more deposition processes, one or more annealing processes, and one or more planarization processes.

In some embodiments, the conductive contacts 312 penetrate through the upper portion 140a and the lower portion 140b of the dielectric layer 140. In some embodiments, the upper portions of the conductive contacts 312 are surrounded by the upper portion 140a of the dielectric layer 140. The lower portions of the conductive contacts 312 are surrounded by the lower portion 140b of the dielectric layer 140.

Many variations and/or modifications can be made to embodiments of the disclosure. The semiconductor nanostructures may have many applicable profiles. The semiconductor nanostructures may include nanosheets, nanowires, or other suitable nanostructures.

Some embodiments relate to the GAA devices. However, embodiments of the disclosure are not limited thereto. Many variations and/or modifications can be made to embodiments of the disclosure. Some other embodiments may relate to planar transistor devices, FinFET devices, GAA devices including forksheets, one or more other applicable devices, or a combination thereof.

Embodiments of the disclosure form a semiconductor device structure with a metal gate stack. A dummy gate stack is laterally surrounded by a dielectric layer. Before replacing the dummy gate stack with the metal gate stack, dopants are introduced into the dielectric layer to tune and/or change the strain of the dielectric layer. Due to the introduced dopants, the trench used to contain the metal gate stack may have profiles that facilitate the filling of metal gate stack. Therefore, the performance and reliability of the semiconductor device structure may therefore be improved.

In accordance with some embodiments, a method for forming a semiconductor device structure is provided. The method includes forming a dummy gate stack over a substrate and forming a dielectric layer laterally surrounding the dummy gate stack. The method also includes introducing dopants into an upper portion of the dielectric layer and removing the dummy gate stack to form a trench surrounded by the dielectric layer. The method further includes forming a metal gate stack in the trench.

In accordance with some embodiments, a method for forming a semiconductor device structure is provided. The method includes forming a dummy gate stack over a substrate and forming a dielectric layer laterally surrounding the dummy gate stack. The method also includes implanting elements into the dielectric layer. The method further includes replacing the dummy gate stack with a metal gate stack after the implanting of the elements.

In accordance with some embodiments, a semiconductor device structure is provided. The semiconductor device structure includes a gate stack over a substrate. The semiconductor device structure also includes a dielectric layer laterally surrounding the gate stack. An upper portion of the dielectric layer comprises dopants, and a lower portion of the dielectric layer is free of the dopants.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a dummy gate stack over a substrate;
forming a dielectric layer laterally surrounding the dummy gate stack;
introducing dopants into an upper portion of the dielectric layer;
removing the dummy gate stack to form a trench surrounded by the dielectric layer; and
forming a metal gate stack in the trench.

2. The method for forming a semiconductor device structure as claimed in claim 1, further comprising thermally annealing the dielectric layer after the dopants are introduced.

3. The method for forming a semiconductor device structure as claimed in claim 1, further comprising thermally annealing the dielectric layer after the dopants are introduced and before the dummy gate stack is removed.

4. The method for forming a semiconductor device structure as claimed in claim 3, wherein the dielectric layer is thermally annealed using a micro-second annealing process.

5. The method for forming a semiconductor device structure as claimed in claim 1, wherein the dopants are introduced using an implantation process.

6. The method for forming a semiconductor device structure as claimed in claim 1, wherein the dopants comprise nitrogen, argon, germanium, or a combination thereof.

7. The method for forming a semiconductor device structure as claimed in claim 1, wherein a lower portion of the dielectric layer is free of the dopants.

8. The method for forming a semiconductor device structure as claimed in claim 7, wherein the upper portion of the dielectric layer has an atomic concentration of the dopants, and the atomic concentration of the dopants gradually decreases from a top of the dielectric layer towards the lower portion of the dielectric layer.

9. The method for forming a semiconductor device structure as claimed in claim 8, further comprising forming a conductive contact in the dielectric layer, wherein an upper portion of the conductive contact is surrounded by the upper portion of the dielectric layer, and a lower portion of the conductive contact is surrounded by the lower portion of the dielectric layer.

10. The method for forming a semiconductor device structure as claimed in claim 1, wherein an upper portion of the trench is wider than a lower portion of the trench.

11. A method for forming a semiconductor device structure, comprising:
forming a dummy gate stack over a substrate;
forming a dielectric layer laterally surrounding the dummy gate stack;
implanting elements into the dielectric layer; and
replacing the dummy gate stack with a metal gate stack after the implanting of the elements.

12. The method for forming a semiconductor device structure as claimed in claim 11, further comprising thermally annealing the elements and the dielectric layer.

13. The method for forming a semiconductor device structure as claimed in claim 12, wherein the elements and the dielectric layer are thermally annealed using a micro-second annealing process.

14. The method for forming a semiconductor device structure as claimed in claim 11, further comprising:
recessing the metal gate stack; and
forming a protective structure over the metal gate stack.

15. The method for forming a semiconductor device structure as claimed in claim 11, wherein a top of the metal gate stack is formed to be wider than a top of the dummy gate stack.

16. A semiconductor device structure, comprising:
a gate stack over a substrate; and
a dielectric layer laterally surrounding the gate stack, wherein an upper portion of the dielectric layer comprises dopants, and a lower portion of the dielectric layer is free of the dopants.

17. The semiconductor device structure as claimed in claim 16, wherein the dopants comprise nitrogen, argon, germanium, or a combination thereof.

18. The semiconductor device structure as claimed in claim 16, wherein the upper portion of the dielectric layer has an atomic concentration of the dopants, and the atomic concentration of the dopants gradually decreases from a top of the dielectric layer towards the lower portion of the dielectric layer.

19. The semiconductor device structure as claimed in claim 16, further comprising a conductive contact penetrating through the upper portion and the lower portion of the dielectric layer.

20. The semiconductor device structure as claimed in claim 16, further comprising a protective structure over the gate stack, wherein a top of the protective structure is closer to a top of the dielectric layer than the gate stack.
